(19) United States
(12) Patent Application Publication
(10) Pub. No.: US 2024/0143280 A1
(43) Pub. Date: May 2, 2024

(54) REDUCTION TREE HAVING INTERMEDIATE QUANTIZATION BETWEEN REDUCTION OPERATORS

(71) Applicant: Xilinx, Inc., San Jose, CA (US)

(72) Inventors: Erwei Wang, London (GB); Samuel Richard Bayliss, Los Altos, CA (US); Philip Bryn James-Roxby, Longmont, CO (US)

(73) Assignee: Xilinx, Inc., San Jose, CA (US)

(21) Appl. No.: 17/975,879

(22) Filed: Oct. 28, 2022

(51) Int. Cl. G06F 7/544; G06F 7/501; H03K 19/20

(52) U.S. Cl. CPC G06F 7/5443; G06F 7/501; H03K 19/20

(57) ABSTRACT

A circuit arrangement includes a reduction operator circuits arranged in a first level of a reduction tree. Each reduction operator circuit accumulates respective products into a respective sum. Quantizer circuits are configured to quantize the sums from the reduction operator circuits into quantized sums, respectively, based on values of the sums relative to respective first thresholds. Another reduction operator circuit is arranged in a second level of the reduction tree and is configured to accumulate the quantized sums and provide a first sum. A second-level quantizer circuit is configured to quantize the first sum into a quantized first sum based on a value of the first sum relative to a second threshold.

### TECHNICAL FIELD

The disclosure generally relates to reduction trees.

### BACKGROUND

In a binary neural network (BNN), the weights and activations are binary values, which significantly reduce hardware requirements for computing products. However, reducing vectors of products to scalar values can become a dominant factor in hardware costs.

Reduction trees can be employed to reduce vectors of products to scalar values. A reduction tree generally has multiple levels of reduction operations (e.g., accumulation circuitry), and in a BNN, the reductions are population counters. Each population counter counts a number of products having a bit value of 1. The next level of the reduction tree accumulates the counted values, and additional levels can accumulate totals from lower levels.

As products of weights and activations can be generated using XNOR gates in a BNN, or as wires and inverters in the case of a fully unrolled BNN, the population counters can be the dominant factor in hardware costs. For example, a fully connected layer in a BNN can require the reduction of hundreds of bits per input channel, which scaled with hundreds of output channels, costs tens of thousands of look-up tables (LUTs) to implement; a convolutional layer can require hundreds of thousands of LUTs. In addition, because the population count of n bits produces a result having [log₂ n]+1 bits, the width of reduction operations in the reduction tree increases logarithmically with each level of the tree.

### SUMMARY

A disclosed circuit arrangement includes a reduction operator circuits arranged in a first level of a reduction tree. Each reduction operator circuit accumulates respective products into a respective sum. Quantizer circuits are configured to quantize the sums from the reduction operator circuits into quantized sums, respectively, based on values of the sums relative to respective first thresholds. Another reduction operator circuit is arranged in a second level of the reduction tree and is configured to accumulate the quantized sums and provide a first sum. A second-level quantizer circuit is configured to quantize the first sum into a quantized first sum based on a value of the first sum relative to a second threshold.

A disclosed method includes running inference on an input tensor by a neural network having a plurality of layers. The method includes providing, for each layer j of the plurality of layers, elements of an output tensor from layer j as input elements to layer j+1 of the neural network. The inference in layer i of the plurality of layers includes quantizing into first quantized sums by first quantizer circuits arranged in a first level of a reduction tree, sums generated by first reduction operator circuits arranged in the first level of the reduction tree, based on values of the sums relative to respective first thresholds. The inference includes inputting the first quantized sums to a first reduction operator circuit arranged in a second level of the reduction tree. The inference includes quantizing by a final quantizer circuit into an element of the output tensor from layer i, a final sum generated by a reduction operator circuit arranged in a last level of the reduction tree, based on a value of the final sum relative to a second threshold.

Another disclosed method includes performing feed forward processing by a neural network. The feed forward processing in layer i of the neural network includes summing products of input activations, initial scaling factors, and weights into partial sums by a partial adder tree. The feed forward processing in layer i includes scaling output from the partial adder tree into scaled output using intermediate scaling factors and generating final sums and an output tensor from the scaled output. The feed forward processing in layer i includes providing the output tensor to layer i+1 of the neural network. The method includes performing backpropagation by the neural network, and the backpropagation includes computing gradient values corresponding to elements of the output tensor from layer i, and updating in layer i, the weights, initial scaling factors, and intermediate scaling factors based on the gradient values. The method includes determining intermediate thresholds for intermediate quantizations in a reduction tree based on trained initial scaling factors and trained intermediate scaling factors.

Other features will be recognized from consideration of the Detailed Description and Claims, which follow.

### BRIEF DESCRIPTION OF THE DRAWINGS

Various aspects and features of the circuits and methods will become apparent upon review of the following detailed description and upon reference to the drawings in which:

FIG. 1 shows an exemplary reduction tree having trained binarization circuits between reduction operators;

FIG. 2 shows an exemplary reduction tree having trained binarization functions between reduction operators, as could be deployed in a fully unrolled BNN;

FIG. 3 shows an exemplary reduction tree having trained intermediate quantizer circuits between reduction operators in multiple levels of the tree;

FIG. 4 shows a functional circuit diagram of a circuit arrangement for training binarization thresholds for intermediate quantizations in a reduction tree of a BNN;

FIG. 5 shows a circuit arrangement for performing residual binarization in the training arrangement of FIG. 4;

FIG. 6 shows a functional circuit diagram of a circuit arrangement for performing inference in a BNN and using reduction trees having trained intermediate quantizations;

FIG. 7 exemplifies training a neural network and parameters used to generate thresholds for intermediate quantizers in reduction trees in the layers of the trained neural network;

FIG. 8 exemplifies inference by a neural network having intermediate quantizers in reduction trees of the layers; and

FIG. 9 is a block diagram depicting a System-on-Chip (SoC) 601 that can host the training of a neural network and inference processing of the neural network consistent with the circuits and methods described herein.

### DETAILED DESCRIPTION

In the following description, numerous specific details are set forth to describe specific examples presented herein. It should be apparent, however, to one skilled in the art, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element.

The disclosed methods and systems employ intermediate quantizer circuits between reduction operators in a reduction tree in order to effectively eliminate intermediate lossless accumulations. The intermediate quantizer circuits improve hardware efficiency by eliminating calculations involving a level of precision that would be lost in the quantization of the final accumulation.

The reduction operator circuits at the lowest level of the reduction tree accumulate products into respective sums, and intermediate quantizer circuits quantize the sums from the lowest-level reduction operator circuits into respective quantized sums. The intermediate quantizations can be based on values of the sums relative to respective thresholds for some applications. The quantized sums are input to a reduction operator circuit in the second level of the reduction tree, which accumulates the quantized sums into another sum, which is quantized by another quantizer circuit.

The reduction trees having intermediate quantizations can be employed in different layers of neural networks as well as in a variety of different types of neural networks. For example, the intermediate quantizations in reduction trees can be used in a deep neural network (DNN) having a cascade of fully connected and convolutional layers, with adjacent layers separated by nonlinearities such as binarization, ReLU or softmax. In some applications, the data and parameters can be quantized into low-precision data formats such as fixed point, block floating point and binary, and the outputs to the summations in multiply-and-accumulate (MAC) operations can be immediately quantized down to those formats before being fed forward for inference.

The intermediate quantizations in reduction trees can be used in a binarized DNN having a cascade of fully connected and convolutional layers. In the binarized DNN, data and parameters are quantized down to one bit, and the outputs to the summations in MAC operations can be immediately binarized using a threshold function before being fed forward for inference.

The intermediate quantizations in reduction trees can be used in a binarized DNN in which every layer is fully unrolled with every MAC operation being spatially one-to-one mapped onto the hardware. The one-to-one mapping has the parameters hardened in logic, and multiplications in MACs can be reduced to either wires or inverters. The outputs to the summations in the MAC operations can be immediately binarized using a threshold function before being fed forward for inference. Though examples shown in the figures and described herein may be directed to binarized neural networks, it will be appreciated that the methods and circuits can be adapted to neural networks that process other data formats, such as floating point, fixed point, block floating point, etc.

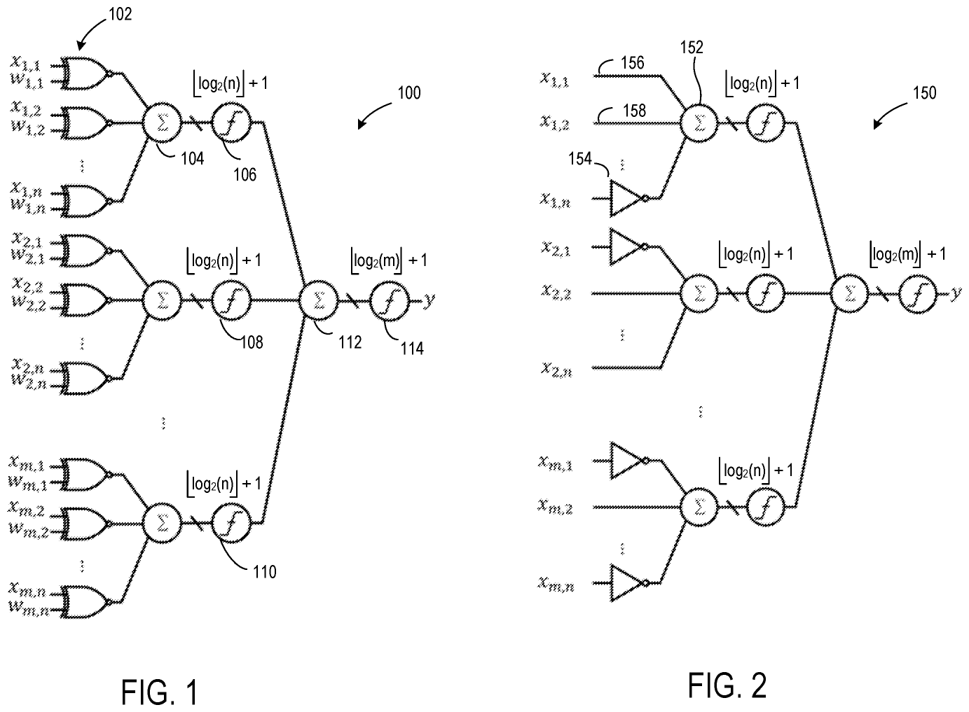

FIG. 1 shows an exemplary reduction tree 100 having trained binarization circuits between reduction operators. The reduction tree can be deployed in a BNN in which the activations and weights are binary values. The binary activations are labeled x_{1,1}, . . . , x_{1,n}, x_{2,1}, . . . , x_{2,n}, . . . , x_{m,1}, . . . , x_{m,n}, and the binary weights are labeled w_{1,1}, . . . , w_{1,n}, w_{2,1}, . . . , w_{2,n}, . . . , w_{m,1}, . . . , w_{m,n}. The products of the binary activations and weights are generated by XNOR gates 102.

The reduction operator circuits in the reduction tree are population counters. Each reduction operator circuit generates a respective sum by counting the number of products having a bit value 1. For example, reduction operator circuit 104 is a population counter that counts the number of products of activations x_{1,1}, . . . , x_{1,n}, and weights w_{1,1}, . . . , w_{1,n}, that have a bit value of 1. The lowest level of the reduction tree has m reduction operator circuits, and each reduction operator circuit accumulates the population count of n products. Each reduction operator circuit produces a result having [log₂ n]+1 bits from the n products.

According to the disclosed approaches, the reduction trees have intermediate quantizers disposed between reduction operators. The quantizer circuits in the exemplary reduction tree 100 are binarization circuits, and the intermediate quantizers are shown as circuit elements 106, 108, and 110. Each binarization circuit compares the count from one of the reduction operator circuits to a respective threshold and generates a bit value based on the count relative to the threshold. For example, if the sum is less than the threshold, the quantized sum can be bit value 0, and if the sum is greater than or equal to the threshold the quantized sum can be bit value 1 (or vice versa). The thresholds can be trained values and stored as registers of the binarization circuits.

The binary outputs from the binarization circuits 106, 108, . . . , 110 are input to the reduction operator circuit 112 in the second level of the reduction tree. The reduction operator circuit 112 is a population counter that counts the number of binary outputs from the m binarization circuits 106, 108, . . . , 110 having a bit value 1. The count generated from the m inputs by population counter 112 has [log₂ m]+1 bits.

The quantizer circuit 114 is a binariziation circuit and generates the final binary output of the reduction tree. Notably, the binariziation circuit 114 reduces the output from circuit 112 from [log₂ m]+1 bits to one bit. Prior art reduction trees lack the binarization circuits 106, 108, . . . , 110 between the reduction operators. Thus, prior art reduction trees would require extra hardware for the reduction operator 112 to handle values from the reduction operator circuits (e.g., 104) having [log₂ n]+1 bits, even though that precision is lost in the final quantization by binarization circuit 114.

FIG. 2 shows an exemplary reduction tree 150 having trained binarization functions between reduction operators, as could be deployed in a fully unrolled BNN. The circuit arrangement of FIG. 2 differs from the circuit arrangement of FIG. 1 in that the products of the activations and weights are not generated by XNOR circuits. Rather, each product is either the binary value of the activation or the inversion of the binary value of the activation, depending on the binary value of the associated weight. The reduction operators and binarization circuits in reduction tree 150 are the same as those elements in the reduction tree 100 of FIG. 1.

Each reduction operator circuit in the first level is coupled to directly input a one-bit activation (x_{i,j}), or to directly input the output from an inverter that is coupled to directly input a one-bit activation. For example, reduction operator circuit 152 is coupled to directly input the activations x_{1,1} and x_{1,2}, (156, 158) and to directly input the output from inverter 154, which inputs activation x_{1,n}.

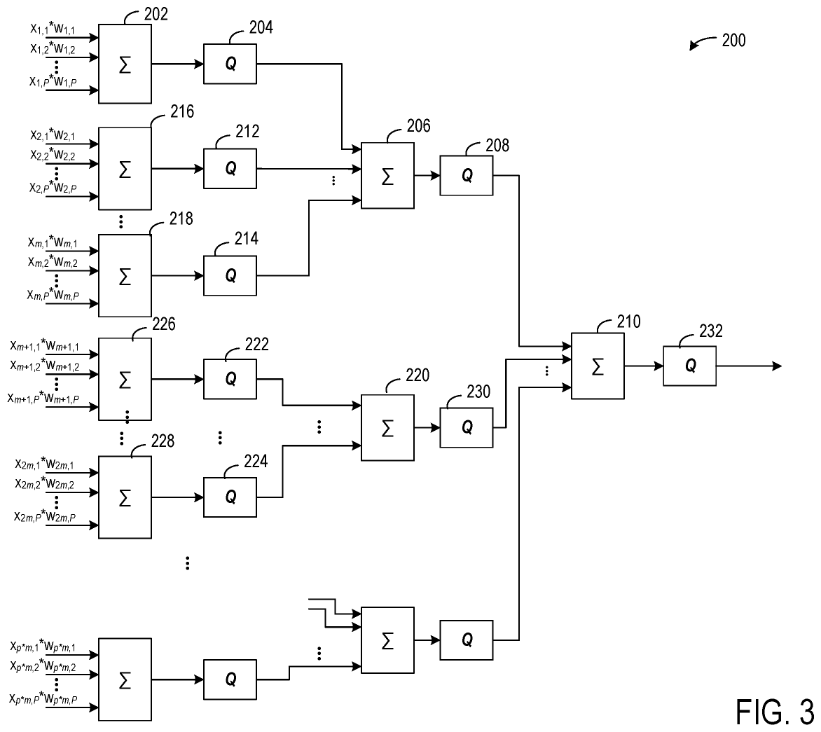

FIG. 3 shows an exemplary reduction tree 200 having trained intermediate quantizer circuits between reduction operators in multiple levels of the tree. The exemplary reduction tree 200 has three levels of reduction operators as compared to the two levels of reduction operators in the reduction trees 100 and 150 in FIGS. 1 and 2. Depending on implementation requirements, a reduction tree can have more than three levels.

Each of the reduction operators in the second level sums quantized sums from a subset of the reduction operators in the first level. For example, reduction operator 206 sums the quantized sums from quantizer circuits 204, 212, . . . , 214, which are quantized sums from the reduction operators 202, 216, . . . , 218. Reduction operator 220 sums the quantized sums from quantizer circuits 222, . . . , 224, which are quantized sums from the reduction operators 226, . . . , 228.

A reduction operator circuit can be a tree of full adder circuits or a population counters depending on application requirements. In a neural network that is not a BNN, each reduction operator circuit in the first level of the reduction tree sums a subset of the products of weights and activations. For example, reduction operator 202 sums the products x_{1,1}*w_{1,1}, x_{1,2}*w_{1,2}, . . . , x_{1,n}*w_{1,n}.

The exemplary reduction tree has trained intermediate quantizer circuits between reduction operators in multiple levels. For example, quantizer circuit 204 quantizes the output from reduction operator 202, the output from quantizer circuit 204 is provided to reduction operator 206, quantizer circuit 208 quantizes the output from reduction operator 206, and the output from quantizer circuit 208 is provided to reduction operator 210. Quantizer circuit 230 quantizes the output from reduction operator 220, and quantizer circuit 232 quantizes the output from reduction operator 210.

In a neural network other than a BNN, the intermediate quantizer circuits in the reduction tree can reduce the precision from one multi-bit value to another multi-bit value of fewer bits. For example, the intermediate quantizer circuits can reduce a value from 16 bits to 8 bits. The quantization can be implemented by a rounding circuit, for example. The intermediate quantizations can have one threshold per bit of each multi-bit value.

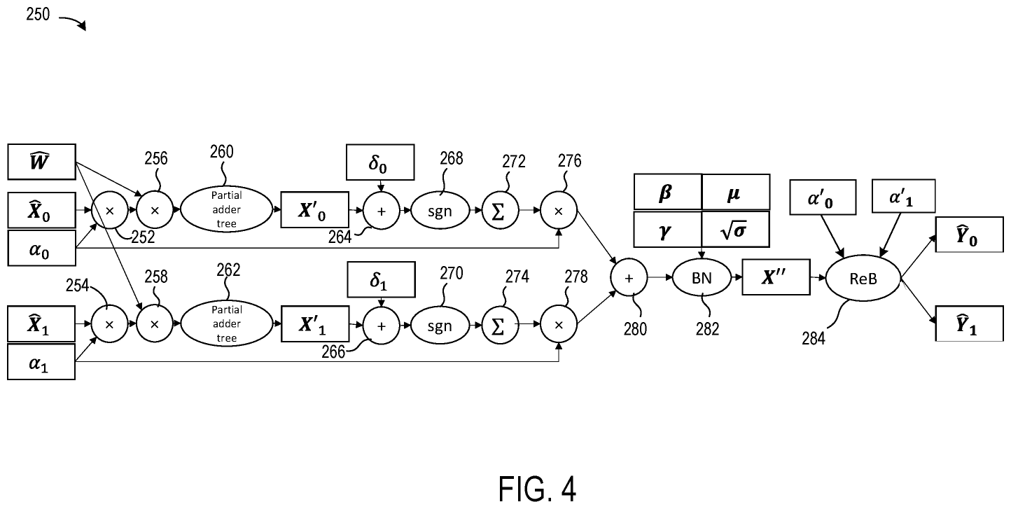

FIG. 4 shows a functional circuit diagram of a circuit arrangement 250 for training binarization thresholds for intermediate quantizations in a reduction tree of a BNN. The training diagram omits the backward propagation, and only shows forward propagation for simplicity. The training diagram representation is similar to the format provided by PyTorch and TensorFlow neural network descriptions, which omit backward propagation and assume the backward propagation diagram to be automatically inferred using the chain rule and tools such as AutoGrad, for example. The functions specified in the training diagram can be implemented by a combination of computing arrangements and specialized circuitry, which can include a central processing unit (CPU), a graphics processing unit (GPU), a system-on-chip (SoC), a tensor processing unit (TPU), a field programmable gate array (FPGA), and an array of multiply-and-accumulate (MAC) circuits.

For a tensor X of full-precision data, \hat{X} represents binarized input activations at training time. To improve the performance of BNNs, residual binarization (“ReB”) is applied to the output in order to improve the data precision. B bits represent each data element of \hat{X}, and B bits represent the trained full-precision scaling factors α₀ and α₁. In the exemplary system, B=2. The goal of residual binarization is to approximate activations X∈ [symbol] ^{M×N} with [symbol] ∈{−1, 1}^{M×N×B} and α∈ [symbol] ^{B}, such that X≈Σ_{b=0}^{B-1}α_{b}\hat{X}_{b}. where M and N are dimensions of X.

Note that \tilde{\hat{X}} represents a tensor at inference time. Every element in \tilde{\hat{X}} has value in set {0, 1}. The training and inference forms can be converted via functions \tilde{\hat{X}}=(\hat{X}+1)/2 and \hat{X}=2\tilde{\hat{X}}−1. In deep neural network training, a standard approach normalizes input activation data to have a mean of zero and a standard deviation of 1 in order to improve the network performance. A single-sided activation data, taking the value of either 0 or 1, would lead to reduced performance, due to an implicit bias of value 0.5.

The input activations are labeled \hat{X}₀ and \hat{X}₁. \hat{X} has a size of MxKxB, where K is the reduction dimension in matrix multiplication, such that (M, K)*(K, N) produces (M, N), and B is the number of bits that represent each element of the tensor. In the exemplary system, B=2, so that \hat{X}₀ is the slice of \hat{X} having the first bits of the MxK elements, and \hat{X}₁ is the slice having the second bits of the elements.

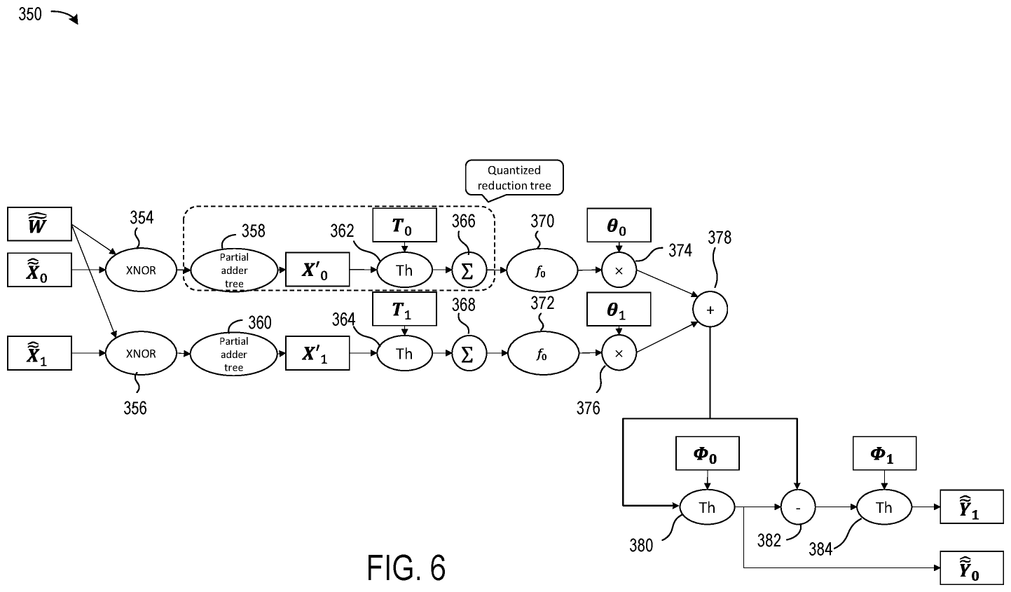

The parameters undergoing training include binary weights Ŵ∈{−1, 1}^{K×N}, scaling factors α₀ and α₁, biases δ₀, δ₁∈ [symbol] ^{N×K/P×B}, batch normalization scaling factors γ, biases β, moving average μ and moving standard deviation \sqrt{σ}. The parameters γ, β, μ, and \sqrt{σ}∈ [symbol] ^{N}. Once trained, the parameters are used to determine the quantization thresholds (T₀, T₁, Φ₀, Φ₁) and scaling factors (θ₀, θ₁) used in the inference arrangement of FIG. 6. P is the number of products involved in computing each partial sum by the partial adder trees 260 and 262 during training.

The weights, activations, and scaling factors can be input from a data bus in a streaming or memory mapped mode, for example, to the training circuitry. Multiplier circuits 252 and 254 generate scaled activations (element-wise) from the input activations and scaling factors (\hat{X}₀×α₀ and \hat{X}₁×α₁), and multiplier circuits 256 and 258 generate products (element-wise) from the scaled activations and weights Ŵ.

Each of partial adder trees 260 and 262 generates a set of partial sums of products from the multiplier circuits 256 and 258, respectively. Each partial sum is a sum of P products. Partial adder tree 260 generates X′₀, and partial adder tree 262 generates X′₁, where X′₀, X′₁∈ [symbol] ^{M×N×K/P}. The P inputs correspond to the inputs to the first-level population counters of FIG. 1, such that the thresholds used by the intermediate quantizer circuits 106, 108, . . . , 110 are determined by the trained a and δ. According to an example,

$${T}_{0} = ( P + \frac{{δ}_{0}}{{α}_{0}} ) / 2 .$$

Note that m in FIG. 1 is equal to K/P, and m*ln=P*K/P=K, which is the total number of inputs to the entire adder tree.

The elements of X′₀ and X′₁ are summed element-wise with scaling factors δ₀ and δ₁ by adders 264 and 266, respectively. The sgn circuit 268 converts each of the sums output by adder 264 into a +1 or −1 value, depending on the sign bit of the sum, and the circuit function 270 similarly converts each of the sums output by adder 266.

From partial adder tree 260 through summation circuit 272, the training circuit performs the accumulation step of a matrix multiplication with sizes (M, K)×(K, N) to produce an output matrix of size (M, N), where K is the reduction dimension. The matrix multiplication outputs of size (M, N) go through batch normalization, which generates output of size (M, N). Summation circuit 272 generates a sum of the values output from the sgn circuit 268, and summation circuit 274 generates a sum of the values output from the sgn circuit 270. Multiplier circuit 276 generates a product of the sum from circuit 272 and the scaling factor α₀, and multiplier circuit 278 generates a product of the sum from circuit 272 and the scaling factor α₁. Adder circuit 280 generates a sum of the products from multiplier circuits 276 and 278.

The batch normalization function 282 inputs scaling factors γ, biases β, moving average μ and moving standard deviation \sqrt{σ} to standardize the sum from adder 280 into intermediate activations X″, where X″∈ [symbol] ^{M×N}. reduction tree quantization.

The residual binarization (“ReB”) function 284 is applied in forward propagation to the intermediate activations X″ using scaling factors α′₀ and α′₁ to generate output activations Ŷ₀ and Ŷ₁.

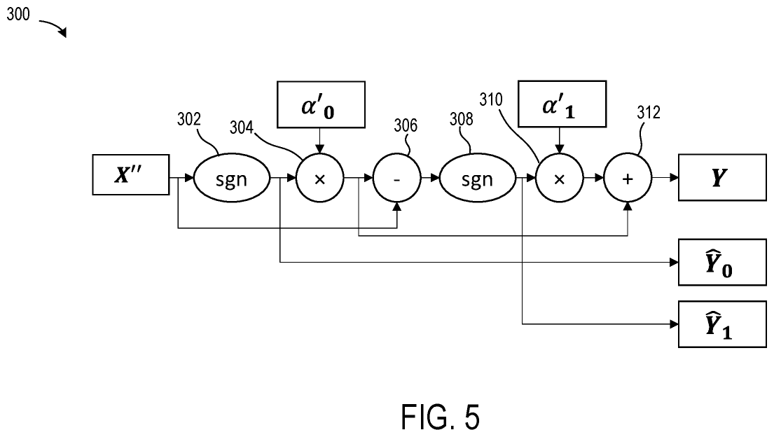

FIG. 5 shows a circuit arrangement 300 for performing residual binarization in the training arrangement of FIG. 4. The sgn circuit 302 converts each of the elements of X″ to a value of −1 or 1 in response to the sign bit of the element, and the multiplier 304 multiplies each of the sign values by the scaling factor α′₀.

The subtraction circuit 306 subtracts, element-wise, the scaled values output by the multiplier 304 from the elements of X″, and the sgn circuit 308 converts each of the values from subtraction circuit 306 to a value of −1 or 1 in response to the sign bit of the value. Multiplier 310 multiplies each of the sign values by the scaling factor α′₁, and adder 312 sum, element-wise, the scaled sign values output by multiplier 310 with the scaled sign values from multiplier 304.

The output Y from adder 312 is used only in training to ensure gradient backward propagation, and Y is not used in inference. Y is used as pre-quantization input to the next layer in training.

FIG. 6 shows a functional circuit diagram of a circuit arrangement 350 for performing inference in a BNN and using reduction trees having trained intermediate quantizations. The quantization thresholds T₀, T₁, Φ₀, and Φ₁ and scaling factors θ₀ and θ₁ are based on the trained parameters from the training arrangement 250 of FIG. 4, where:

$${T}_{0} = ( P + \frac{{δ}_{0}}{{α}_{0}} ) / 2 , {T}_{1} = ( P + \frac{{δ}_{1}}{{α}_{1}} ) / 2 where {T}_{0} , {T}_{1} ∈ {ℝ}^{N \times \frac{K}{P} \times B}$$

$${θ}_{0} = {α}_{0} \times γ / \sqrt{σ} , {θ}_{1} = {α}_{1} \times γ / \sqrt{σ} , {θ}_{0} , {θ}_{1} ∈ {ℝ}^{N}$$

$${Φ}_{0} = μ + ( {α}_{0}^{′} - β ) \sqrt{σ} / γ , {Φ}_{1} = μ + ( {α}_{1}^{′} - β ) \sqrt{σ} / γ , {Φ}_{0} , {Φ}_{1} ∈ {ℝ}^{N} .$$

The trained binary weights \tilde{Ŵ}∈{0, 1}^{K×N} weights and input activations \tilde{\hat{X}}₀, \tilde{\hat{X}}₁∈{0, 1}^{M×K×B} can be input from a data bus in a streaming or memory mapped mode, for example, to the inference circuitry. XNOR circuitry 354 and 356 generate binary products (element-wise) from the activations and weights \tilde{Ŵ}.

The partial adder tree 358 generates sums from subsets having P elements of the outputs from XNOR circuitry 354, and partial adder tree 360 generates sums from subsets having P elements of the outputs from XNOR circuitry 356. As in FIG. 1, the partial adder trees can include population counters that count in each subset of P outputs the number of outputs having a bit value of 1. The sums from partial adder tree 358 are X′₀, and the sums from partial adder tree are X′₁, where X′₀, X′₁∈ [symbol] ^{M×N×K/P×B}.

Threshold circuits 362 and 364 perform intermediate quantizations (binarization in the example) of the elements of X′₀, and X′₁, based on the trained intermediate quantization thresholds T₀ and T₁, respectively.

The inputs to summation circuits 366 and 368 are matrices of size (M, N, K/P), and summation circuits 366 and 368 perform summation across the third dimension K/P, resulting in output matrices of size (M, N). Inputs to threshold circuits 362 and 364 are matrices of size (M, N, K/P), and T₀ and T₁ are of size (N, K/P) of threshold values. T₀ and T₁ are broadcast into shape (M, N, K/P) by threshold circuits 362 364 in applying the element-wise threshold operation. Threshold circuits 362 and 364 generate output matrices of size (M, N, K/P).

The circuits 370 and 372 implement instances of the ƒ₀ function (ƒ₀(X)=2X−1) in order to convert data from \tilde{\hat{X}} format (format at inference time {0,1}) to \hat{X} format (binarized input activations at training time {−1,1}), so as to enable the application of scaling factors θ₀ and θ₁.

The multiplier circuits 374 and 376 scale output values from the instances 370 and 372 of the ƒ₀ function, and the adder circuit 378 sums each output element from multiplier circuit 374 with the corresponding output element from multiplier circuit 376.

Threshold circuit 380 quantizes (binarization in the example) the elements generated by adder circuitry 378 based on the trained quantization threshold Φ₀. The output from threshold circuit 380 is also provided as input to subtraction circuit 382, which subtracts, element-wise, the output from threshold circuit 380 from the output of adder 378. The output from subtraction circuit 382 is provided as input to threshold circuit 384, which quantizes (binarization in the example) the elements generated by subtraction circuitry 382 based on the trained quantization threshold Φ₁. The binary activations from threshold circuits 380 and 384 can be provided as input activations \tilde{Ŷ}₀ and \tilde{Ŷ}₁ to the next layer of the neural network, respectively.

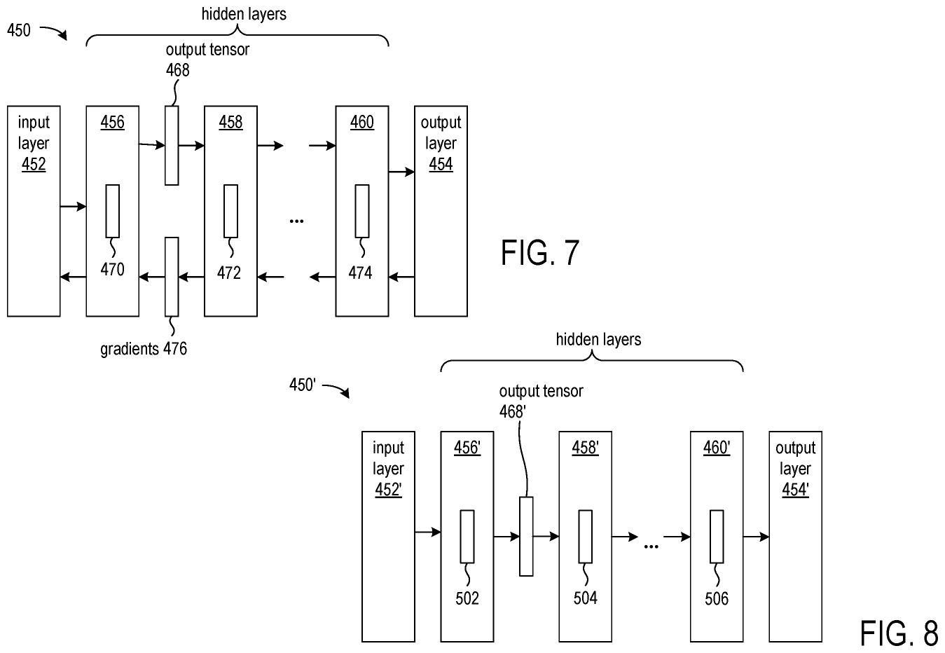

FIG. 7 shows a dataflow that exemplifies training a neural network and parameters used to generate thresholds for intermediate quantizers in reduction trees in the layers of the trained neural network. The neural network 450 generally includes an input layer 452, an output layer 454, and multiple hidden layers 456, 458, . . . , 460. During feed forward processing, hidden layer 456 generates output tensor 468 based on parameters 470. The parameters include α, δ, γ, β, μ, and \sqrt{σ} as described above. Hidden layers 458, . . . , 460 also generate output tensors (not shown) and can similarly use corresponding sets 472 and 474 of the aforementioned parameters. During backpropagation, gradients are computed and communicated to adjust the values of the parameters. For example, layer 456 inputs the gradients 476 computed in layer 458, and the values of the parameters 470 can be updated based on the gradients. The training system can improve the accuracy of the trained network by approximating the gradient of quantization functions at the intermediate levels of the reduction trees. In response to errors induced by the approximations, the training system allows for retraining of post-approximation network.

Training of the neural network involves the training system determining a level of accuracy by comparing results produced at the output layer 454 to predetermined reference results after a plurality of training iterations. The training can be terminated in response to completing a predetermined number of training iterations, or in response to changes in levels of accuracy from one iteration to the next consistently falls below a given threshold for a number of consecutive iterations.

FIG. 8 shows a dataflow that exemplifies inference by a neural network 450′ having intermediate quantizers in reduction trees of the layers. The layers of neural network 450′ correspond to the layers of neural network 450 in the training example of FIG. 7. One or more of the layers 456′, 458′, . . . , 460′ can include reduction trees having intermediate quantizers. For example, hidden layer 456′ has a reduction tree(s) 502, and the reduction tree(s) includes intermediate quantizers as described herein. Blocks 504 and 506 exemplify reduction trees having intermediate quantizers in hidden layers 458′ and 460′. The thresholds used by the intermediate quantizers of reduction tree 502 are based on the parameters 470 trained in FIG. 7.

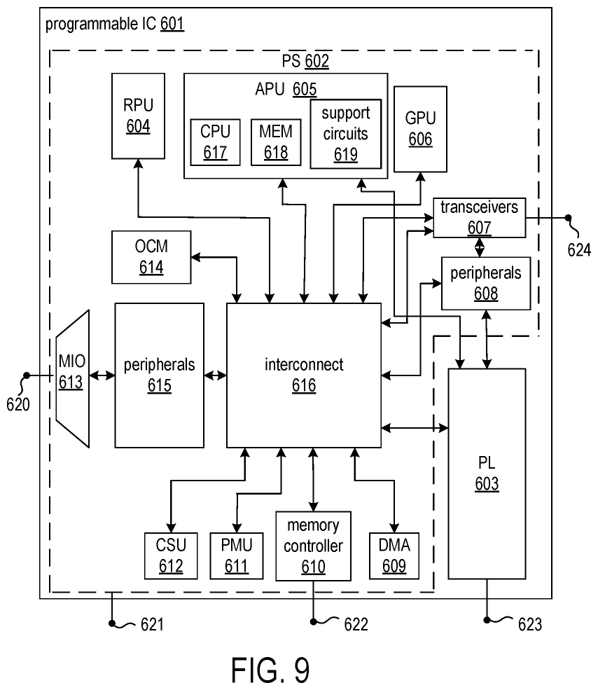

FIG. 9 is a block diagram depicting a System-on-Chip (SoC) 601 that can host the training of a neural network and inference processing of the neural network consistent with the circuits and methods described herein. In the example, the SoC includes the processing subsystem (PS) 602 and the programmable logic subsystem 603. The processing subsystem 602 includes various processing units, such as a real-time processing unit (RPU) 604, an application processing unit (APU) 605, a graphics processing unit (GPU) 606, a configuration and security unit (CSU) 612, and a platform management unit (PMU) 611. The PS 602 also includes various support circuits, such as on-chip memory (OCM) 614, transceivers 607, peripherals 608, interconnect 616, DMA circuit 609, memory controller 610, peripherals 615, and multiplexed (MIO) circuit 613. The processing units and the support circuits are interconnected by the interconnect 616. The PL subsystem 603 is also coupled to the interconnect 616. The transceivers 607 are coupled to external pins 624. The PL 603 is coupled to external pins 623. The memory controller 610 is coupled to external pins 622. The MIO 613 is coupled to external pins 620. The PS 602 is generally coupled to external pins 621. The APU 605 can include a CPU 617, memory 618, and support circuits 619. The APU 605 can include other circuitry, including L1 and L2 caches and the like. The RPU 604 can include additional circuitry, such as L1 caches and the like. The interconnect 616 can include cache-coherent interconnect or the like.

Referring to the PS 602, each of the processing units includes one or more central processing units (CPUs) and associated circuits, such as memories, interrupt controllers, direct memory access (DMA) controllers, memory management units (MMUs), floating point units (FPUs), and the like. The interconnect 616 includes various switches, busses, communication links, and the like configured to interconnect the processing units, as well as interconnect the other components in the PS 602 to the processing units.

The OCM 614 includes one or more RAM modules, which can be distributed throughout the PS 602. For example, the OCM 614 can include battery backed RAM (BBRAM), tightly coupled memory (TCM), and the like. The memory controller 610 can include a DRAM interface for accessing external DRAM. The peripherals 608, 615 can include one or more components that provide an interface to the PS 602. For example, the peripherals can include a graphics processing unit (GPU), a display interface (e.g., DisplayPort, high-definition multimedia interface (HDMI) port, etc.), universal serial bus (USB) ports, Ethernet ports, universal asynchronous transceiver (UART) ports, serial peripheral interface (SPI) ports, general purpose (GPIO) ports, serial advanced technology attachment (SATA) ports, PCIe ports, and the like. The peripherals 615 can be coupled to the MIO 613. The peripherals 608 can be coupled to the transceivers 607. The transceivers 607 can include serializer/deserializer (SERDES) circuits, MGTs, and the like.

Various logic may be implemented as circuitry to carry out one or more of the operations and functions described herein and/or shown in the figures. In these contexts, a circuit or circuitry may be referred to as “logic,” “module,” “engine,” or “block.” It should be understood that logic, modules, engines and blocks are all circuits that carry out one or more of the operations/activities. In certain implementations, a programmable circuit is one or more computer circuits programmed to execute a set (or sets) of instructions stored in a ROM or RAM and/or operate according to configuration data stored in a configuration memory.

Though aspects and features may in some cases be described in individual figures, it will be appreciated that features from one figure can be combined with features of another figure even though the combination is not explicitly shown or explicitly described as a combination.

The circuits and methods are thought to be applicable to a variety of systems employing reduction trees. Other aspects and features will be apparent to those skilled in the art from consideration of the specification. The circuits and methods can be implemented as one or more processors configured to execute software, as an application specific integrated circuit (ASIC), or as a logic on a programmable logic device. It is intended that the specification and drawings be considered as examples only, with a true scope of the invention being indicated by the following claims.

What is claimed is:

1. A circuit arrangement, comprising:
a first plurality of reduction operator circuits arranged in a first level of a reduction tree, each reduction operator circuit of the first plurality of reduction operator circuits configured to accumulate a respective plurality of products into a respective sum;
a first plurality of quantizer circuits configured to quantize the sums from the first plurality of reduction operator circuits into a first plurality of quantized sums, respectively, based on values of the sums relative to respective first thresholds;
a first reduction operator circuit arranged in a second level of the reduction tree and configured to accumulate the first plurality of quantized sums and provide a first sum; and
a first second-level quantizer circuit configured to quantize the first sum into a quantized first sum based on a value of the first sum relative to a second threshold.

2. The circuit arrangement of claim 1, wherein the first plurality of reduction operator circuits in the first level and the first reduction operator circuit in the second level are configured to count bits having a bit value of 1 in the plurality of products.

3. The circuit arrangement of claim 2, wherein:
each quantizer circuit of the first plurality of quantizer circuits is configured to quantize the respective sum into a bit value 1 or a bit value 0; and
the first second-level quantizer circuit is configured to quantize the first sum into a bit value 1 or a bit value 0.

4. The circuit arrangement of claim 1, wherein the plurality of reduction operator circuits in the first level and the reduction operator circuit in the second level are full adders.

5. The circuit arrangement of claim 1, further comprising:
a second plurality of reduction operator circuits arranged in the first level of the reduction tree, each reduction operator circuit of the second plurality of reduction operator circuits configured to accumulate a respective plurality of products into a respective sum;
a second plurality of quantizer circuits configured to quantize the sums from the second plurality of reduction operator circuits into a second plurality of quantized sums, respectively, based on values of the sums relative to respective third thresholds;
a second reduction operator circuit arranged in the second level of the reduction tree and configured to accumulate the second plurality of quantized sums and provide a second sum;
a second, second-level quantizer circuit configured to quantize the second sum into a quantized second sum based on a value of the second sum relative to a fourth threshold;
a third reduction operator circuit arranged in a third level of the reduction tree and configured to accumulate the quantized first sum and quantized second sum and provide a third sum; and
a third-level quantizer circuit configured to quantize the third sum into a quantized third sum based on a value of the third sum relative to a fifth threshold.

6. The circuit arrangement of claim 1, further comprising a plurality of XNOR circuits configured to generate the plurality of products in response to pairs of one-bit activations and one-bit weights, wherein the first plurality of reduction operator circuits in the first level and the first reduction operator circuit in the second level are configured to count bits having a bit value of 1 in the plurality of products.

7. The circuit arrangement of claim 1, wherein:
each reduction operator circuit of the first plurality of reduction operator circuits is coupled to directly input a one-bit activation or output from an inverter that is coupled to directly input a one-bit activation; and
the first plurality of reduction operator circuits in the first level and the first reduction operator circuit in the second level are configured to count bits having a bit value of 1 in the plurality of products.

8. A method, comprising:
running inference on an input tensor by a neural network having a plurality of layers; and
providing, for each layer j of the plurality of layers, elements of an output tensor from layer j as input elements to layer j+1 of the neural network;
wherein the inference in layer i of the plurality of layers includes:
quantizing into first quantized sums by first quantizer circuits arranged in a first level of a reduction tree, sums generated by first reduction operator circuits arranged in the first level of the reduction tree, based on values of the sums relative to respective first thresholds, and inputting the first quantized sums to a first reduction operator circuit arranged in a second level of the reduction tree; and
quantizing by a final quantizer circuit into an element of the output tensor from layer i, a final sum generated by a reduction operator circuit arranged in a last level of the reduction tree, based on a value of the final sum relative to a second threshold.

9. The method of claim 8, wherein the inference in layer i of the plurality of layers includes:
counting bits having a bit value of 1 by the first reduction operator circuits; and
counting bits having a bit value of 1 by the reduction operator circuit in the last level of the reduction tree.

10. The method of claim 9, wherein:
the quantizing by the first quantizer circuits includes quantizing into a bit value 1 or a bit value 0, each sum of the sums generated by the first reduction operator circuits; and
the quantizing by the final quantizer circuit includes quantizing the final sum into a bit value 1 or a bit value 0.

11. The method of claim 8, wherein the first reduction operator circuits and the reduction operator circuit in the last level of the reduction tree are full adders, and the inference in layer i of the plurality of layers includes:
summing input products into the sums generated the first reduction operator circuits; and
summing values generated in a next-to-last level of the reduction tree into the final sum generated by the reduction operator circuit in the last level of the reduction tree.

12. The method of claim 8, wherein the inference in layer i of the plurality of layers includes:
quantizing into second quantized sums by second quantizer circuits arranged in the first level of the reduction tree, sums generated by second reduction operator circuits arranged in the first level of the reduction tree, based on values of the sums relative to respective third thresholds, and inputting the second quantized sums to a second reduction operator circuit arranged in the second level of the reduction tree;
generating a first sum from the first quantized sums by the first reduction operator circuit in the second level of the reduction tree;
generating a second sum from the second quantized sums by the second reduction operator circuit in the second level of the reduction tree;
quantizing the first sum by a first quantizer circuit in the second level of the reduction tree into a first, second-level quantized sum based on a value of the first sum relative to a fourth threshold;
quantizing the second sum by a second quantizer circuit in the second level of the reduction tree into a second, second-level quantized sum based on a value of the second sum relative to a fifth threshold; and
generating a third-level sum from the first, second-level quantized sum and second, second-level quantized sum by a third reduction operator circuit in a third level of the reduction tree.

13. The method of claim 8, wherein the inference in layer i of the plurality of layers includes:
generating a plurality of products by a plurality of XNOR circuits in response to pairs of one-bit activations and one-bit weights; and
counting bits having a bit value of 1 by the first reduction operator circuits .

14. A method, comprising:
performing feed forward processing by a neural network, including in a layer i of the neural network:
summing products of input activations, initial scaling factors, and weights into partial sums by a partial adder tree;
scaling output from the partial adder tree into scaled output using intermediate scaling factors;
generating final sums and an output tensor from the scaled output; and
providing the output tensor to layer i+1 of the neural network;
performing backpropagation by the neural network, including:
computing gradient values corresponding to elements of the output tensor from layer i; and
updating in layer i, the weights, initial scaling factors, and intermediate scaling factors based on the gradient values; and
determining intermediate thresholds for intermediate quantizations in a reduction tree based on trained initial scaling factors and trained intermediate scaling factors.

15. The method of claim 14, wherein the determining intermediate thresholds includes determining each intermediate threshold as a function of numbers of products in each partial sum, the trained initial scaling factors, and the trained intermediate scaling factors.

16. The method of claim 14, further comprising:
performing backpropagation by the neural network, including updating a final scaling factor, a batch normalization scaling factor, a batch bias, a moving average, and a moving standard deviation based on the gradient values; and
determining a final quantization threshold for a final quantization in a last level of the reduction tree based on a trained final scaling factor, a trained batch normalization scaling factor, a trained batch bias, a trained moving average, and a trained moving standard deviation.

17. The method of claim 14, wherein the summing includes counting bits having a bit value of 1 in the products.

18. The method of claim 14, wherein the input activations are binarized input activations, and the weights are binary weights.

19. The method of claim 14, wherein the input activations have values of either 0 or 1, and the weights have values of either −1 or 1.

20. The method of claim 14, wherein the partial sums are real values.
